(19) United States
(12) Patent Application Publication
(10) Pub. No.: US 2010/0055699 A1
(43) Pub. Date: Mar. 4, 2010

(54) METHOD OF MANUFACTURING A SEMICONDUCTOR SENSOR DEVICE AND SEMICONDUCTOR SENSOR DEVICE OBTAINED WITH SUCH METHOD

(75) Inventor: Neriman Nicoletta Kahya, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/517,378

(22) PCT Filed: Dec. 5, 2007
(86) PCT No.: PCT/IB07/54932

§ 371 Date: Jun. 3, 2009

(30) Foreign Application Priority Data
Dec. 8, 2006 (EP) 06125712.7
Aug. 2, 2007 (EP) 07113655.0

(51) Int. Cl. C12Q 1/68; H01L 29/66; H01L 21/02

(52) U.S. Cl. 435/6; 257/414; 438/49; 257/E21.002; 257/E29.166

(57) ABSTRACT

The invention relates to a method of manufacturing a semiconductor sensor device (10) for sensing a substance (30) and comprising a strip-shaped semiconductor region (1) which is formed on a surface of a semiconductor body (11) and which is connected at a first end to a first electrically conducting connection region (3) and at a second end to a second electrically conducting connection region (4) while a fluid (20) comprising a substance (30) to be sensed can flow along a side face of the strip-shaped semiconductor region (1) and the substance (30) to be sensed can influence the electrical properties of the strip-shaped semiconductor region (1), and wherein the strip-shaped semiconductor region (1) is formed in a semiconductor layer (13) on top of an insulating layer (5) which in turn is on top of a semiconductor substrate (14). According to the invention after formation of the strip-shaped semiconductor region (1) in the semiconductor layer (13), the substrate (2) is attached to the part of the semiconductor body (11) comprising the strip-shaped semiconductor region (1) at a side opposite to the semiconductor substrate (14), whereinafter the semiconductor substrate (14) is at least partially and preferably completely removed and subsequently an opening (6) is formed in the insulating layer (5) at the location of the strip-shaped semiconductor region (1). This method is suitable for mass scale production and protects the parts of the device (10) that are prone to damage caused by the fluid (20).

### FIELD OF THE INVENTION

The invention relates to a method of manufacturing a semiconductor sensor device for sensing a substance and comprising a strip-shaped semiconductor region which is formed on a surface of a semiconductor body comprising a substrate and which is connected at a first end to a first electrically conducting connection region and at a second end to a second electrically conducting connection region while a fluid comprising a substance to be sensed can flow along a side face of the strip-shaped semiconductor region and the substance to be sensed can influence the electrical properties of the strip-shaped semiconductor region, and wherein the strip-shaped semiconductor region is formed in a semiconductor layer on top of an insulating layer which in turn is on top of a semiconductor substrate.

Such a method is very suitable for making sensor devices for detecting chemical and/or biochemical substances. In the latter case it can e.g. be used for detecting antigen/antibody bindings, biomolecules and others with a high sensitivity and reproducibility, and thus it can be used advantageously in gene analysis, disease diagnostics and the like. Moreover, the detection of simpler molecules like chemical substances that are volatile or dissolved in a liquid is also possible, e.g. by introduction by the substance of charges on the strip-shaped semiconductor region of which the conductivity is thus changed. Here with strip-shaped semiconductor region a body is intended having at least one lateral dimension between 1 and 100 nm and more in particular between 10 and 50 nm. The region may be like a nano-wire and having dimensions in two lateral directions that are in the said ranges. The length of the strip-shaped semiconductor region may be in the range of 100 to 30000 nm.

### BACKGROUND OF THE INVENTION

A method as mentioned in the opening paragraph is known from the German patent application that has been published under number DE 102 54 158 on Jun. 9, 2004. In this document, for obtaining a sensor device, a number of strip-shaped semiconductor regions are formed in the silicon region of a SOI (=Silicon On Insulator) wafer which silicon region is present on top of the BOX (=Buried Oxide) region. The strip-shaped semiconductor region here forms a part of a so-called FIN FET (=Field Effect Transistor) having electrically conducting connection regions on top of source/drain regions that border the end faces of the strip-shaped semiconductor regions. A side face of the strip-shaped semiconductor region running perpendicular to the (main) surface of the semiconductor body is used to sense the presence of a biological entity such as a cell. A plurality of strip-shaped semiconductor regions are used to obtain a more or less fixed position of the biomolecule to be detected on the surface of the semiconductor body. The Fin FET technology is attractive for forming a biosensor device since this technology is very well compatible with a standard IC technology like a (BI)(C)MOS (=(Bipolar)(Complimentary)(Metal Oxide Semiconductor) technology.

A drawback of the known method is that it is less suitable for mass production of semiconductor devices comprising a sensor. Moreover, the device obtained may easily be damaged by the fluid containing the substance to be detected, in particular if such fluid comprises a bodily liquid. The latter danger can be larger if other circuitry is present in the device since such circuitry may be more prone to such damage.

### SUMMARY OF THE INVENTION

It is therefore an object of the present invention to avoid the above drawbacks and to provide a method, which is suitable for large scale manufacturing of semiconductor devices comprising a sensor that is not prone to damages caused by the fluid containing the substance to be detected.

To achieve this, a method of the type described in the opening paragraph is characterized in that after formation of the strip-shaped semiconductor region in the semiconductor layer, the substrate is attached to the part of the semiconductor body comprising the strip-shaped semiconductor region at a side opposite to the semiconductor substrate, whereinafter the semiconductor substrate is at least partially removed and subsequently an opening is formed in any remaining part of the semiconductor substrate and in the insulating layer at the location of the strip-shaped semiconductor region. In this way, the strip-shaped semiconductor region can be very locally approached by the fluid containing the substance from a side of the insulating layer which is opposite to the side where the silicon is present in which the strip-shaped semiconductor region and possible other circuitry is formed. Preferably the substrate is removed completely.

Furthermore, contact between a large part of the sensing element (including other circuitry) that may be damaged by the fluid is avoided since the main side of the semiconductor body where the sensing element and other circuitry is formed is now covered by the substrate. The substrate can be easily selected to be inert towards e.g. bodily fluids since it may comprise glass, quartz or even a resin. It may be attached to the semiconductor body by a simple and cheap technique like gluing.

The method according to the invention is also very suitable for mass-scale production since the substrate-transfer technique used in the method according to the present invention is very suitable for mass scale Front End Of Line production. The semiconductor substrate can be completely or partially removed by etching or chemical-mechanical polishing or combinations thereof. An additional advantage of the method according to the present invention is that it offers a simple possibility of packaging the semiconductor sensor device.

In a preferred embodiment the strip-shaped semiconductor region and the electrically conducting connection regions are buried in a further insulating layer to which the substrate is attached. In this way, the substrate can be more easily attached since the buried further insulating layer can be used to planarize the surface facing the substrate. Moreover, it forms an electrically insulating region around the contact wiring of the strip-shaped semiconductor region or around other circuitry if present including its wiring.

A further embodiment is characterized in that the opening in the insulating layer is formed so deep that a cavity in the further insulating layer is formed along the side faces of the strip-shaped semiconductor region. In this way all four side faces of the strip-shaped semiconductor region can become available to the fluid containing the substance to be detected. The sensitivity of the sensor device may be increased in this way.

Preferably an electrically conducting region is formed in the further insulating layer positioned viewed in projection above the strip-shaped semiconductor region. Such a conducting region can be used as a so-called back gate for the strip-shaped semiconductor region that forms the channel region of a FET transistor which enable a precise control and regulation of the part of the strip-shaped semiconductor region that forms the channel region of the FET transistor which is exposed to the (charges of) a biomolecule attaching or approaching the semiconductor region. Another advantage of such an electrically conducting region is that when subjected to alternative currents, it can be used to mix the fluid containing the substance to be detected. This would result in faster detection.

In a further preferred embodiment a plurality of strip-shaped semiconductor regions is formed, preferably running mutually parallel. This may have several advantages. One possibility is to use this feature to increase the sensitivity of the sensor towards the substance to be detected. Other possibilities are to use different strip-shaped semiconductor regions to detect different biomolecules or to detect different concentrations of the same biomolecule. In the latter case the strip-shaped semiconductor regions could be covered by thin dielectric layer having different thicknesses or could feature different doping levels or could have different dimensions (length, lateral dimensions) in order to distinguish between different concentrations.

Preferably, the window is formed by means of etching using a photo-lithographically patterned photo resist layer as a mask and channels are formed in the photo resist layer that cross the strip-shaped semiconductor region(s) and through which the fluid comprising the substance to be detected will flow. Or else, in the case the silicon is only partially removed, the channels are formed in the silicon with the same method. In this way, the manufacture is not only simple since it comprises not many steps but it also allows for an easy integration of the packaging of the semiconductor sensor, i.e. the formation of a complete sensor device including transport tubes and in- and outlet connections, e.g. for a pump.

In another attractive embodiment also other electronic elements are formed in a part of the semiconductor body that viewed in projection is adjacent to the part of the semiconductor body in which the strip-shaped semiconductor region is formed. In this way additional circuitry, e.g. logic, can be easily integrated. Such circuitry, e.g. made in a CMOS process, can be connected to different strip-shaped semiconductor regions such that these can measure different biomolecules or different concentrations. The circuitry can also contain algorithms that analyze the data with respect to correlations of signals from different elements. In this way the accuracy of the detection can be improved. Furthermore, logic circuitry can be use to compensate for some non-idealities in the detection, such as a reduced specificity in the molecular binding of the receptor. If the circuitry can process the data from all the different arrays (of strip-shaped semiconductor regions) and can give the results of the sample analysis (presence of which biomolecules and/or at which concentration), no external chip is needed for the purpose. Thus, a fully integrated chip results, containing not only the detector but also the analysis and data processing logic.

In addition the circuitry may contain other useful electronic elements like a heating element (resistor) or a temperature sensor or a photo detector (diode or transistor) in case the detection of the relevant substance is done in an optical manner.

Preferably the substance to be detected is a particle such as a biomolecule like a protein and at least one side surface of the strip-shaped semiconductor region is covered with receptor molecules like antibodies to which the biomolecule can attach. In this way, biomolecules that indicate e.g. a disease or an infection can be detected at a very low concentration and thus at a very early stage of the disease or infection. This is favorable for treating such disease, like cancer, or infection in manner as prophylactic as possible.

Finally, the invention also comprises a semiconductor sensor device obtained by a method according to the invention.

### BRIEF DESCRIPTION OF THE DRAWINGS

These and other aspects of the invention will be apparent from and elucidated with reference to the embodiments described hereinafter, to be read in conjunction with the drawing, in which

FIGS. 1 through 9 are sectional or top views of a semiconductor sensor device at various stages in its manufacture by means of a method in accordance with the invention,

FIG. 10 is a sectional view of another semiconductor sensor device at a relevant stage in its manufacture by means of another method in accordance with the invention,

FIGS. 11 and 12 are top views of other semiconductor sensor devices in a relevant stage of its manufacture by means of yet another method in accordance with the invention, and

FIG. 13 is a sectional view of a relevant part of the semiconductor sensor device at a stage in its manufacture corresponding to FIG. 9.

FIG. 14 shows an advantageous embodiment of a FinFET with a back-gate after processing.

FIG. 15 shows a schematic of PCR amplification and subsequent hybridization of the PCR product on the semiconductor sensor device surface.

FIG. 16 shows a schematic of PCR amplification and subsequent capture of the PCR product by antibodies on the semiconductor sensor device surface.

### DETAILED DESCRIPTION OF EMBODIMENTS

The Figures are diagrammatic and not drawn to scale, the dimensions in the thickness direction being particularly exaggerated for greater clarity. Corresponding parts are generally given the same reference numerals and the same hatching in the various Figures.

Where in the present invention the term “particle” is used, reference may be made to chemical, biochemical or biological particles, e.g. that need to be detected, such as for example but not limited to cells, cellular organelles, membranes, bacteria, viruses, chromosomes, DNA, RNA, small organic molecules, metabolites, proteins including enzymes, peptides, nucleic acid segments, spores, micro-organisms and fragments or products thereof, polymers, metal ions, toxins, illicit drugs, explosives, etc. Particles, especially smaller particles such as e.g. some DNA, RNA, nucleic acid segments etc., also may be coupled to larger particles. The particles may be biological cells.

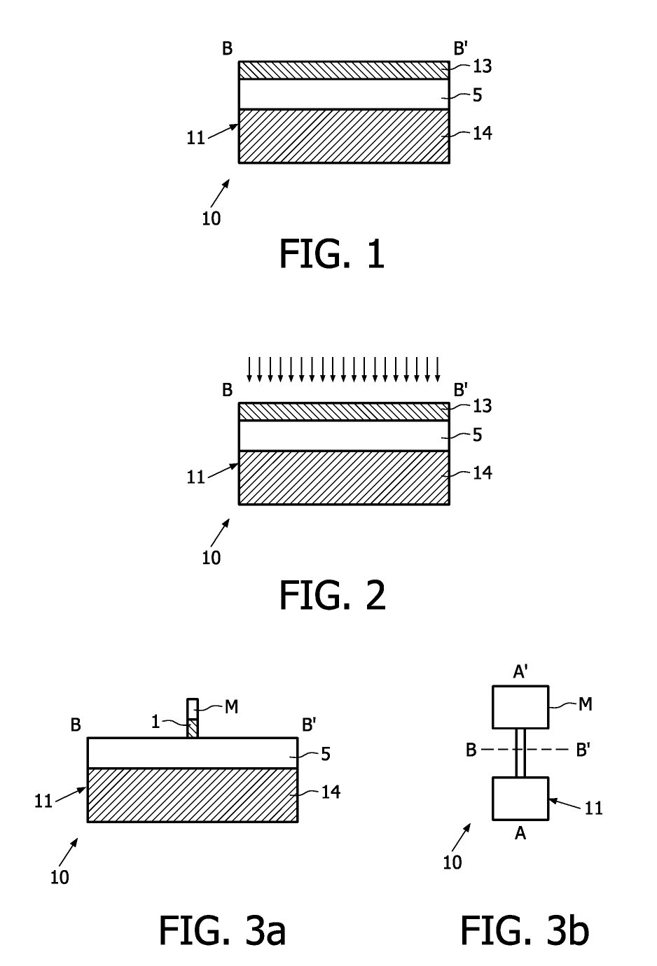

FIGS. 1 through 9 are sectional or top views of a semiconductor sensor device at various stages in its manufacture by means of a method in accordance with the invention. The b Figures comprise the top views in which the outer borders of the semiconductor body are omitted, while the other Figures comprise sectional views.

FIGS. 1 through 4 are sectional views of a semiconductor sensor device at various stages in its manufacture by means of a method in accordance with the invention. The semiconductor sensor device 10 to be manufactured may contain already various elements or components at an earlier stage than the stage in FIG. 1. Such elements or components are not shown in the drawing. Such elements can also be formed at a later stage of the manufacture and in any case will be shown in the Figures that relate to the last stages in the manufacture.

In a first relevant step of the manufacture of the device 10 (see FIG. 1) a silicon substrate 14 forming a silicon semiconductor body 11, is provided with an insulating layer 5 and on top thereof a monocrystalline silicon layer 13. Such a semiconductor body 11 can e.g. be obtained by implanting oxygen ions into a monocrystalline silicon substrate. However, other techniques to obtain such a start-point semiconductor body 11 are feasible, e.g. using thermal oxidation of a semiconductor substrate, wafer bonding of a further semiconductor substrate to the thermal oxide layer and split-off of the largest part of the wafer bonded further semiconductor substrate at the location of a hydrogen or helium implant into the latter formed before the bonding step.

Subsequently and in so far as desired (see FIG. 2) an implant I may be performed to tune the electrical properties of the semiconductor/silicon layer 13.

Hereinafter (see FIGS. 3a and 3b) a hard mask layer M, e.g. of silicon nitride or a silicon oxide, is deposited and patterned on the semiconductor layer 13 at the location of the strip-shaped semiconductor region 1 to be formed and where source and drain regions are envisaged for forming a FinFET device comprising the mesa-shaped semiconductor region 1. This is followed by an etching step to form said regions. Optionally this may be followed by a surface treatment like an H₂ annealing step.

Then (see FIGS. 4a and 4b) a poly silicon layer or hard mask layer N is deposited and patterned after which source and drain implants S,D implants are done for forming source and drain regions 31,41 that border the fin 1. During each of these two implants (S,D) the other region is protected by e.g. a photo resist spot, which is not shown in the drawing.

Next (see FIGS. 5a and 5b) the hard mask layer N is removed again by (selective) etching and electrically conducting connection regions 3,4 are formed e.g. in the form of copper studs or an aluminum wiring pattern.

In the next stage (see FIG. 6) the semiconductor body 11 also comprises further semiconductor elements 9,9′ which have been mentioned before and that can be formed before, during or after formation of the Fin FET and preferably during said Fin FET formation. Said further elements 9,9′ can comprise logic for controlling the functioning of the semiconductor sensor device 10 and will be provided with wiring 19. Wiring 19 and connection regions 3,4 including a wiring or conductor-strip pattern connected thereto are buried in a further electrically insulating layer 7, which may comprise a silicon oxide like silicon dioxide and is deposited e.g. by means of CVD (=Chemical Vapor Deposition).

Hereinafter (see FIG. 7) a substrate 2, e.g. of glass or quartz or a resin, is attached to the further insulating layer 7 by means of gluing.

This step is followed by (see FIG. 8) by removal of the silicon semiconductor substrate 14 by means of etching or CMP (=Chemical Mechanical Polishing) or a combination of such techniques. In this way the lower side of the insulating layer 5 is made free.

Next (see FIG. 9) a photo resist layer 40, preferably a positive resist layer such as BCB, is deposited and patterned on the free surface of the insulating layer 5. This is followed by forming an opening 6 in the insulating layer 5 at the location of the strip-shaped semiconductor region 1. This is done here by means of etching, which etching is continued after opening insulating layer 5 and in this way an open cavity is formed in the further insulating layer 7 which surrounds the strip-shaped region 1. The latter can now be reached by a fluid 20 containing a substance to be detected while the side with the source/drain regions 41, 31 of the Fin FET and elements 9, 9′ including wiring 3, 4, 19 are protected by the substrate 2 against said fluid 20.

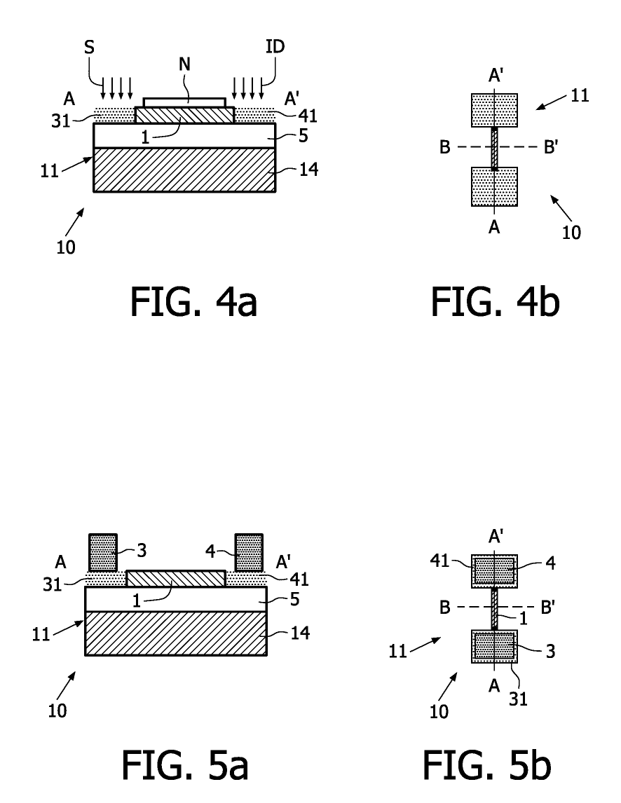

FIG. 10 is a sectional view of another semiconductor sensor device at a relevant stage in its manufacture by means of another method in accordance with the invention. In this modification (see FIG. 10) a further connection region 8 is embedded into the further insulating layer 7 which is positioned opposite to the strip-shaped semiconductor region 1 and which may be used as a back gate in the Fin FET.

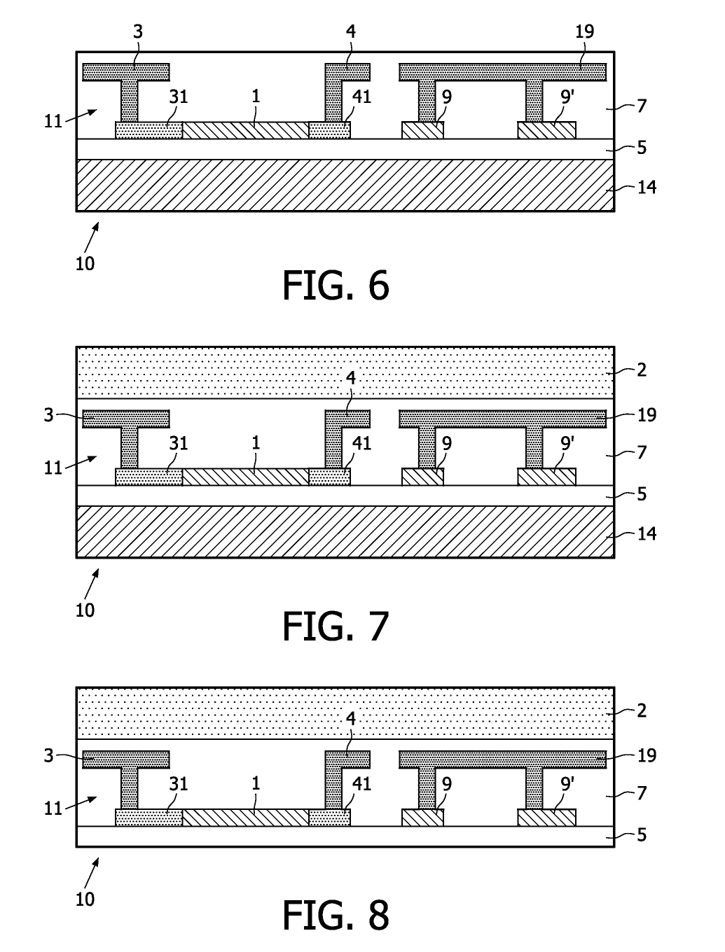

FIGS. 11 and 12 are top views of other semiconductor sensor devices in a relevant stage of its manufacture by means of yet another method in accordance with the invention. In a modification of the first example (see FIG. 11) a plurality of mutually parallel strip-shaped semiconductor regions 1,1′,1″ are formed, e.g. for detecting different components, or different concentrations of the same component or to increase the sensitivity of the sensor device 10. The Figure also shows that in the patterned resist layer 40 channels 50 are formed that may be used to transport the fluid 20 containing the substance to be detected towards the strip-shaped semiconductor regions 1,1′,1″ of the Fin FET(s). At the border of the semiconductor body 11 said channels 50 can be connected to e.g. a pump (not shown) or a vessel for collecting the fluid 20. The upper side of the channels can be closed by fixing yet another substrate, e.g. also of glass, quartz or a resin, to the upper surface of the resist layer 40.

In another modification (see FIG. 12) also a plurality of strip-shaped semiconductor regions 1,1′,1″ are used which are connected at one end to a common source region 31, while at the other ends separate drain regions 41, 41′ are formed.

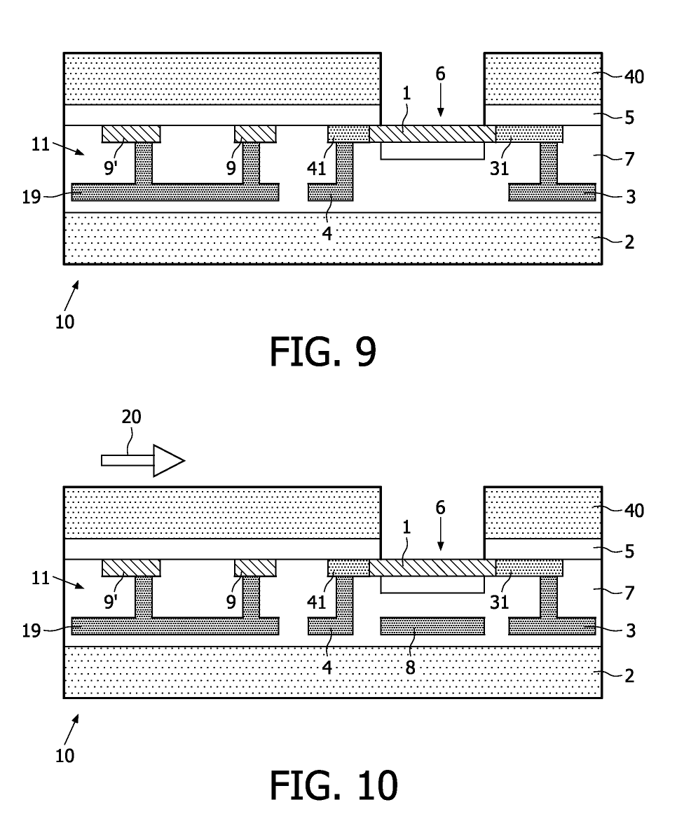

FIG. 13 is a sectional view of a relevant part of the semiconductor sensor device at a stage in its manufacture corresponding to FIG. 9. In the Figure a layer of receptor molecules 60 is shown comprising e.g. antibodies to which a protein 30 can be selectively be attached. The adhesion of the receptor molecules 60 can be improved by treating the surface by building a monolayer of certain suitable molecules like of a poly-ethylene-glycol polymer or an amino-alky-carbon acid.

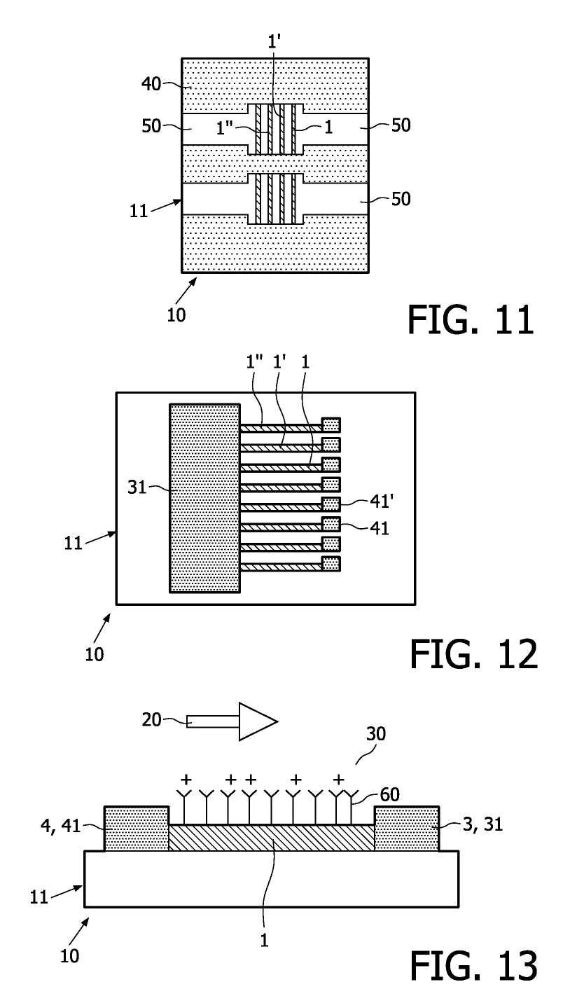

The semiconductor sensor devices of FIGS. 9-13 can be used advantageously for label-free quantitative analysis of nucleic acids through polymerase chain reaction (PCR) amplification. FIG. 14 shows an advantageous embodiment of a FINFET with a back-gate after processing. Having the back-gate close to the Fin allows an improved electrical detection accuracy and improved sensitivity.

Polymerase chain reaction (PCR) is a well established method of amplification of nucleic acids of specific sequence, see for instance “A-Z of Quantitative PCR”, ed. by S. A. Bustin. International University Line, La Jolla, Calif., 2004-2006.

PCR primers bind to the sequence of template of nucleic acid to be amplified and initiate the polymerization reaction via a suitable polymerase. In order to optimize each step, PCR is performed in a number of thermocycles (often 30 to 40), that is the temperature is cycled between three values for about 30 to 40 times. Quantitative PCR enables the user to monitor the progress of the PCR reaction as it occurs, i.e. in real time, thereby giving information on the initial copy number of nucleic acid present in the sample. The amplicons are hybridized to complementary nucleotides, so-called capture probes, to form the PCR product. The progress of the amplification reaction is measured in terms of quantification of the amount of PCR product detected in various ways, mainly optically (fluorescence). Amplification and hybridization are usually carried out in solution (homogeneous assay) in separate compartments/tubes. A recent approach, called solid-phase PCR, combines amplification (in solution) and hybridization (on pre-treated solid surfaces) in one compartment, which avoids the transfer of chemicals between separate compartments and allows for monitoring the progress of the amplification reaction as it occurs.

The main advantages of employing the semiconductor sensor devices, such as FinFETs, for a quantitative PCR device are the following:

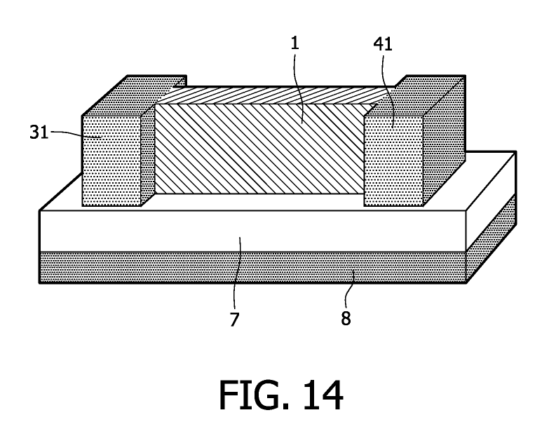

The electrical detection is label-free (see FIG. 15). There is no need for labelled primers and there is no need for an expensive optical detection system.

Because of the very high sensitivity (in the fMol/l range) of the semiconductor sensor devices, quantitative information is detectable at early stages of the PCR.

In addition, the semiconductor sensor devices (such as FinFETs) can be manufactured with good process control, have reproducible electrical properties of the contacts and allow the manufacturing of many sensors in parallel (multiplexing) with standard processing techniques. Because the back-gate 8 has been separated from the wet part of the sensor (on the top of the semiconductor sensor device), the electronics are separated from the micro fluidics to a large extent.

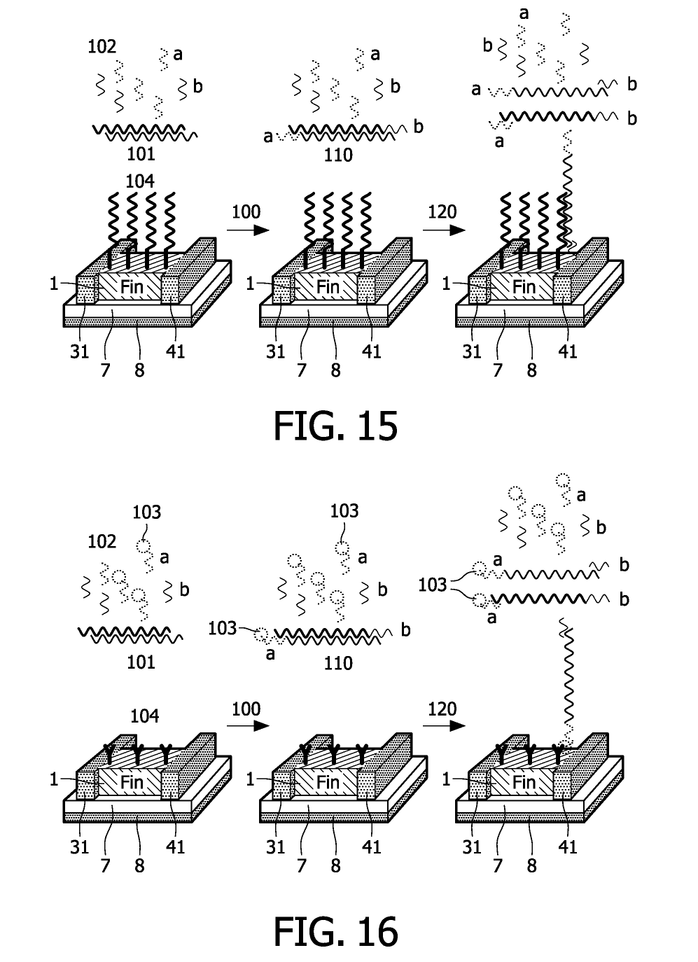

Semiconductor sensor devices (such as FinFETs), which are usually made from Si or Si compounds, can be functionalized to covalently attach oligonucleotides of any wanted sequence (see FIG. 15) or antibodies (see FIG. 16). For this purpose, the surface modification of semiconductor sensor devices (such as FinFETs) is carried out via reaction with silyl-alkyl-aldheides, aminosilanes, epoxysilanes, or through deposition of self-assembled monolayers or functionalized polymers, e.g. PEG or polysilanes.

It is desirable to have a selective reaction between the gate dielectric and the silicon areas. The reactions mentioned above are not selective to the gate dielectric.

Therefore, the surface modification is done at an early stage, as shown in FIG. 9. Both the resist layer 40 and the gate dielectric react with silyl-alkyl-aldheides, aminosilanes, epoxysilanes, or through deposition of self-assembled monolayers or functionalized polymers, e.g. PEG or polysilanes. When the resist layer 40 is removed, a modified gate dielectric is obtained while the other silicon areas such as the source and drain areas remain unattached. In this way selectivity between the gate dielectric and the other silicon areas has been obtained.

Placed into a device for performing the thermocycle, functionalized FinFETs are able to detect the PCR product 110 in real-time upon hybridization 120 with the complementary oligonucleotide attached to the FinFET surface (see FIG. 15) or upon recognition of the antigen (which is attached to one of the primers), by the antibody covalently bound to the FinFET surface (see FIG. 16).

FIG. 15 shows a first use of the semiconductor sensor device in PCR amplification 100 and subsequent hybridization 120 of the PCR product 110 on the semiconductor sensor surface. In this specific embodiment the semiconductor sensor device is a FinFET.

The PCR mixture, containing the DNA template 101 and the primers 102 (a,b), is added to the microarray of FinFETs coated with capture probes 104, which are oligonucleotides with a sequence complementary to that of one strand of the amplicon. When the thermocycle is started, specific segments of the DNA template will be amplified. Part of the amplicons (PCR product) hybridize to the capture probes on the FinFET surface and, thereby, generate an electric signal. In each cycle, there is a competition between elongation and hybridization of the amplicons. Therefore, only some of the generated amplicons will actually hybridize on the surface and generate the electric signal. This amount reflects the amount of amplicons present in the total solution. If the electric signal is recorded during the annealing phase of each cycle, the amplification of DNA can be followed over time. As for the conventional quantitative PCR, a curve of standards with known initial DNA copy number should be measured. The cycle number at which a threshold electric signal is achieved in the sample will be a measure of the initial DNA copy number.

FIG. 16 shows a second use of the semiconductor sensor device in PCR amplification 100 and subsequent capture of the PCR product 110 by antibodies on the semiconductor sensor device surface. This embodiment relies on immunodetection of the PCR product on the FinFET surface. The PCR mixture, containing the DNA template 101 and primers 102 (a,b) (of which at least one 102 (a) is labelled with biotin), is added to the microarray of FinFETs coated with anti-biotin antibodies. When the thermocycle is started, specific segments of the DNA template will be amplified. The biotin-containing amplicons (PCR product 110) will bind to the anti-biotin antibodies on the FinFET surface and, thereby, generate an electric signal. If the electric signal is recorded during the annealing phase of each cycle, the amplification of DNA can be followed over time. As for the conventional quantitative PCR, a curve of standards with known initial DNA copy number should be measured. The cycle number at which a threshold electric signal is achieved in the sample will be a measure of the initial DNA copy number.

The biotin label 103 is only one example. Other labels, which are epitopes to available antibodies, can be used as well.

FinFETs can be coupled to capture probes 104 of different sequence, thereby conferring ability to multiplex and simultaneously detect different segments of DNA in the same compartment (if FinFETs are in the same compartments) or in separate compartments (if FinFETs are positioned in separate compartments).

All of the embodiments described above apply not only to DNA but also to all types of nucleic acids and structured probes, i.e. RNA, PNA (peptide nucleic acid), LNA (locked nucleic acid), ANA (arabinonucleic acid), or HNA (hexitol nucleic acid) oligonucleotide. RNA, PNA, LNA, and HNA are able to form hybrids with DNA that are more stable that DNA:DNA homoduplexes. This ensures enhanced discrimination ability for sequence mismatches (more specific hybridization). Hybrids can also be specifically detected with suitable antibodies.

It will be obvious that the invention is not limited to the examples described herein, and that within the scope of the invention many variations and modifications are possible to those skilled in the art.

For example it is to be noted that the invention is not only suitable for the manufacture of a sensor comprising a large number of strip-shaped semiconductor regions but also a small number of such regions or even a single one is a feasible selection. In this way one single Fin FET (with a plurality of sensing elements) or a plurality of Fin FETS (with a single of a few sensing elements) are feasible. Although in the example Fin FET(s) are used in order to optimize the sensitivity of the sensor, the device and manufacture may be simplified by using only a single (low) doping level and type for the whole semiconductor body. Also in this case an image charge introduced in the strip-shaped semiconductor body by the substance 30 to be detected can change the conductivity of the fin sufficiently to be detected using a simple current measurement between connection region attached to the fin.

An advantage of the embodiments of the invention is that the detection time can be significantly reduced because the channel is close to the fluid comprising the substance. Reduction of the detection time is in particular desirable for low analyte concentrations to be detected of nanomolar levels and below, e.g. in the range of fMol/l.

Furthermore it is noted that various modifications are possible with respect to individual steps. For example other deposition techniques can be selected instead of those used in the example. The same holds for the materials selected. Thus, for insulating layers other dielectrics can be used than a silicon nitride or oxide.

Finally, it is to be noted that the unit can be transferred to various handling substrate materials, such as flexible foils, or other handling materials with other special properties as and when needed.

1. Method of manufacturing a semiconductor sensor device (10) for sensing a substance (30) and comprising a strip-shaped semiconductor region (1) which is formed on a surface of a semiconductor body (12) comprising a substrate (2) and which is connected at a first end to a first electrically conducting connection region (3) and at a second end to a second electrically conducting connection region (4) while a fluid (20) comprising a substance (30) to be sensed can flow along a side face of the strip-shaped semiconductor region (1) and the substance (30) to be sensed can influence the electrical properties of the strip-shaped semiconductor region (1), and wherein the strip-shaped semiconductor region (1) is formed in a semiconductor layer (13) on top of an insulating layer (5) which in turn is on top of a semiconductor substrate (14), characterized in that after formation of the strip-shaped semiconductor region (1) in the semiconductor layer (13), the substrate (2) is attached to the part of the semiconductor body (11) comprising the strip-shaped semiconductor region (1) at a side opposite to the semiconductor substrate (14), whereinafter the semiconductor substrate (14) is at least partially removed and subsequently an opening (6) is formed in any remaining part of the semiconductor substrate (14) and in the insulating layer (5) at the location of the strip-shaped semiconductor region (1).

2. Method according to claim 1, characterized in that the strip-shaped semiconductor region (1) and the electrically conducting connection regions (3,31,4,41) are buried in a further insulating layer (7) to which the substrate (2) is attached.

3. Method according to claim 1, characterized in that the opening (6) in the insulating layer (5) is formed so deep that a cavity in the further insulating layer (7) is formed along the side faces of the strip-shaped semiconductor region (1).

4. Method according to claim 2, characterized in that an electrically conducting region (8) is formed in the further insulating layer (7) which is positioned viewed in projection above the strip-shaped semiconductor region (1).

5. Method according to claim 1, characterized in that a plurality of strip-shaped semiconductor regions (1,1′,1″) is formed, preferably running mutually parallel.

6. Method according to claim 5, characterized in that different strip-shaped semiconductor regions (1,1′) of the plurality of strip-shaped semiconductor regions (1,1′,1″) are formed such that different substances (30,30′) can be detected or different concentrations of the same substance (30).

7. Method according to claim 1, characterized in that the semiconductor substrate (14) is removed completely.

8. Method according to claim 1, characterized in that the window (6) is formed by means of etching using a photo-lithographically patterned photo resist layer (40) as a mask and that also channels (50) are formed in the photo resist layer (40) and any remaining part of the semiconductor substrate (14) that cross the strip-shaped semiconductor region(s) (1,1′,1″) and through which the fluid (20) comprising the substance (30) to be detected will flow.

9. Method according to claim 1, characterized in that also other electronic elements (9,9′) are formed in a part of the semiconductor body (11) that viewed in projection is adjacent to the part of the semiconductor body in which the strip-shaped semiconductor region (1,1′,1″) is formed.

10. Method according to claim 1, characterized in that the substance (30) to be detected is a biomolecule like a protein and at least one side surface of the strip-shaped semiconductor region is covered with receptor molecules (60) like antibodies to which the biomolecule can attach.

11. Semiconductor sensor device (10) obtained by a method according to claim 1.

12. Use of the semiconductor sensor device according to claim 1 for quantitative analysis of nucleic acids through PCR amplification.
